(19) United States
(12) Patent Application Publication
(10) Pub. No.: US 2011/0187205 A1
(43) Pub. Date: Aug. 4, 2011

(54) Circuit Arrangement for Supplying a Field Device of Automation Technology

(75) Inventor: Jiri Karbula, Riehan (CH)

(73) Assignee: Endress +Hauser Flowtec AG, Reinach (CH)

(21) Appl. No.: 12/086,881

(22) PCT Filed: Dec. 5, 2006
(86) PCT No.: PCT/EP2006/069346

§ 371 Date: Feb. 14, 2011

(30) Foreign Application Priority Data
Dec. 29, 2005 (DE) 10 2005 063 054.5

(51) Int. Cl. G01R 1/20

(52) U.S. Cl. 307/154

(57) ABSTRACT

A circuit arrangement CA for supplying a field device F1 of automation technology includes a consumer circuit CC, a direct-voltage converter G and an input circuit IC having a 2-conductor connection CN. The input circuit IC includes a modulator unit M, which is connected with a current regulating circuit RC and the direct-voltage converter G. The modulator unit M so controls the direct-voltage converter G that an adjustable total current IS is carried by the 2-conductor connection CN. Use of the controlled direct-voltage converter G enables an optimum power transfer to the consumer circuit CC.

The invention relates to a circuit arrangement for supplying a field device of automation technology.

In automation technology, field devices are often used, to serve for measuring and/or influencing process variables. Examples of such field devices are fill-level measuring devices, mass-flow measuring devices, pressure and temperature measuring devices, etc., which, as sensors, register the corresponding process variables, fill-level, flow (e.g. flow rate), pressure and temperature.

Field devices serving, as actuators, to influence process variables include, e.g., valves for controlling flow of a liquid in a section of pipeline or pumps for controlling fill level in a container.

A large number of such field devices are manufactured and sold by the firm, Endress+Hauser.

As a rule, field devices in modern manufacturing plants are connected via fieldbus systems (HART, Profibus, Foundation Fieldbus, etc.) to superordinated units (e.g. control systems or control units). These superordinated units serve, among other things, for process control, process visualization, process monitoring, as well as for tasks such as commissioning field devices. Also falling under the heading “field devices” are, in general, such units (e.g. remote I/Os, gateways, linking devices) as are directly connected to a fieldbus and serve for communication with the superordinated units.

Many field devices are obtainable in 2-conductor versions. In such case, the energy, or power, supply of the field device is accomplished using the same line-pair used for communication.

In contrast to 2-conductor devices, 4-conductor devices need an additional line-pair for the energy supply. This, naturally, increases the cabling effort.

In the case of 2-conductor devices, the available power is, most often, subject to certain limitations. The input voltage varies, normally, between 10 and 36 V. In the case of a 4-20 mA current loop, typically, a minimum of 4 mA is available at an input voltage of about 12 V. In order to be able to match the power in the field device appropriately to demands, the power available on the input side must first be ascertained. This is done via measurement of the terminal voltage and the value of the loop current that has been set.

The excess loop current must be drained off via a parallel voltage regulator. Moreover, a DC-DC switching regulator is necessary, in order to keep the input voltage to an unregulated, direct-voltage converter (DC-DC converter) constant. The direct voltage converter serves for supplying a consumer unit, which typically is composed of a CPU, a measurement amplifier and a sensor. The direct-voltage converter serves, at the same time, for galvanic separation of the consumer unit from the 2-conductor supply voltage. Clocked converters permit a direct-voltage conversion at a relatively high degree of efficiency. They are, therefore, frequently used in the case of field devices.

The known circuit arrangements for field devices, which also permit power matching, have multiple regulators, which, in each case, lead to undesired losses. Moreover, the individual control circuits are relatively complex. For a power matching, the power available on the input side must first be ascertained complexly. Then, this information must be transmitted to the consumer side. Only then can a changing of the energy consumption be introduced.

An object of the invention is to provide a field-device circuit arrangement having an especially simple construction, enabling simple power matching, and producing only little lost power.

This object is achieved by the features given in claim 1, as follows:

Circuit arrangement for supplying a field device of automation technology, including an input circuit having a 2-conductor connection, a direct-voltage converter connected thereto, and a consumer circuit, characterized in that the input circuit includes a modulator unit, which is connected with a current regulating circuit and with the direct-voltage converter and which so controls the direct-voltage converter that an adjustable total current I_{S} is carried by the 2-conductor connection.

Advantageous further developments of the invention are given in the dependent claims.

An essential idea of the invention is to utilize for the supply a controlled direct-voltage converter, which serves for the galvanic separation and with which the current carried by the 2-conductor connection can be adjusted. On the consumer side, the excess current is measured. It is a direct measure for the power available there. By simple minimizing of the excess current, the consumption on the consumer side can be optimally matched. Through use of the circuit arrangement, the power available on the input side can be optimally applied.

For the signal transmission (e.g. 4-20 mA-signal), only the measured value must be transmitted from the consumer unit to the primary side of the direct-voltage converter. Measurement of the power available on the input side is not necessary. In turn, also the transmission of such information from the primary side to the consumer side is not needed. The circuit arrangement has, in principle, only one regulator, and produces significantly less losses as compared with the known circuit arrangements.

The invention will now be explained on the basis of an example of an embodiment presented in the drawing, the figures of which show as follows:

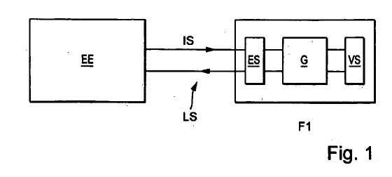

FIG. 1 block diagram of a field device of automation technology and a receiving unit;

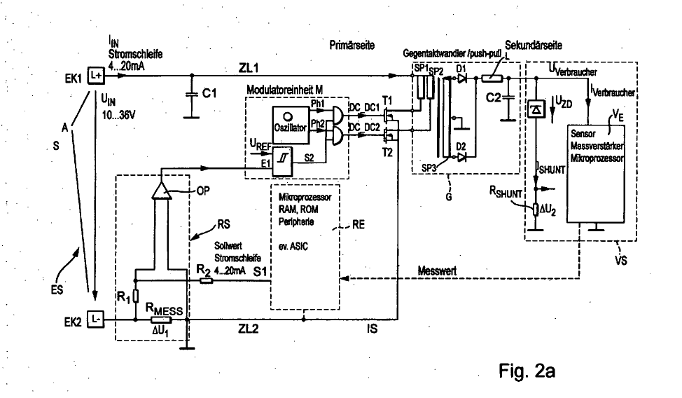

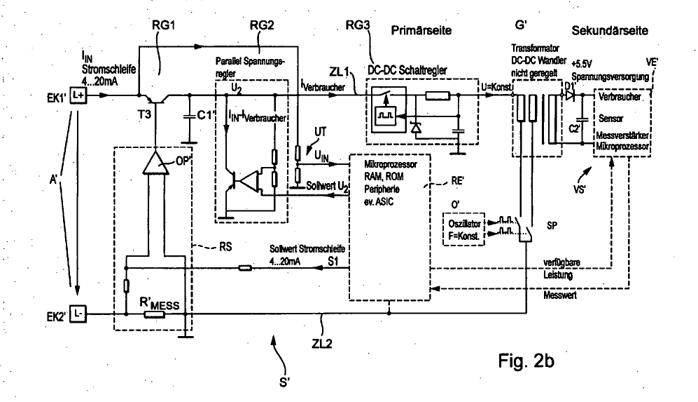

FIG. 2a circuit arrangement of the invention;

FIG. 2b circuit arrangement of the state of the art;

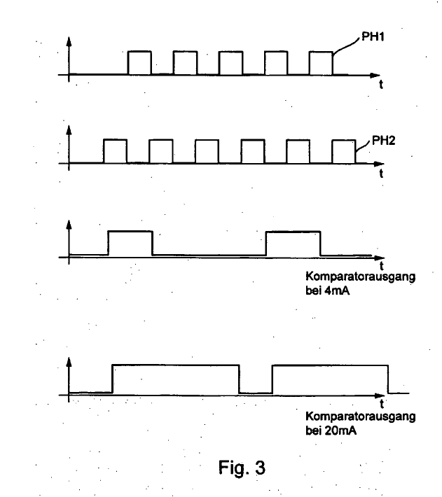

FIG. 3 output signal as a function of time for a comparator provided in the circuit arrangement of FIG. 2a.

FIG. 1 shows a block diagram of a field device F1 of automation technology, and a receiving unit RU. In the present case, connection between field device F1 and receiving unit RU is via a 2-conductor current loop CL. Thereby, a measured value taken by the field device F1 can be transmitted as a 4-20 mA current signal I_{S} to the receiving unit RU.

Field device F1 is composed, essentially, of an input circuit IC, a direct-voltage converter G and a consumer circuit CC. The direct-voltage converter G cares for the galvanic separation between the primary-side, electrical current circuit and the consumer, electrical current circuit on the secondary side.

FIG. 2a shows the circuit arrangement CA of the invention for the field device F1 in more detail. Included are a 2-conductor connection CN for the connecting with the 2-conductor current loop CL. Connection CN is composed of two input terminals IT1 and IT2. A lead line LL1 leads from the input terminal IT1 to a direct-voltage converter G. Also, lead line LL1 is connected with a capacitor C1. Leading from the input terminal IT2 is a lead line LL2 likewise going to the direct-voltage converter G via a measuring resistor R_{Meas}. The measuring resistor R_{Meas} is part of a current regulating circuit RC, which also includes a resistor R1 and an operational amplifier OP connected thereafter.

Additionally connected with LL1 is a computer unit CU, which can be e.g. an ASIC or also a microprocessor with memory components and appropriate peripherals.

An essential component of the circuit arrangement CA is a modulator unit M composed of a comparator K, an oscillator O and two AND-gates AG1, AG2. The output of the comparator K and two pulse outputs Ph1 and Ph1 of the oscillator O are, in each case, connected with the inputs of the AND-gates AG1 and AG2, respectively. The AND-gates AG1 and AG2 control the power transistors T1 and T2, respectively. The two power transistors T1, T2 are in the lead line LL2.

The direct-voltage converter G is a push-pull converter and is composed, typically, of three coils CO1, CO2, CO3, two rectifying diodes D1, D2, a choke coil L and a storage capacitor C2. The output of the direct-voltage converter G is connected with the consumer circuit CC. The consumer circuit CC is composed mainly of the actual consumer essentials unit CE (sensor, measurement amplifier and microprocessor). Connected in parallel with the consumer essentials unit CE are a Zener diode Z and a shunt resistor R_{Shunt}.

FIG. 2b shows a conventional circuit arrangement CA′ for the field device F1. It, too, has a 2-conductor connection CN′ for connecting with the 2-conductor current loop CL. Connector CN′ is composed of two input terminals ITV and IT2′. A lead line LL1′ leads from the input terminal IT1′, via a DC-DC switching regulator RG3, to a direct-voltage converter G′. Likewise connected with the lead line LL1′ is a capacitor C1′. Before the capacitor C1′ is arranged a power transistor T3, which serves as current regulator RG1 and is controlled by a current regulating circuit RC′. Leading from the input terminal IT2 is a lead line LL2′ likewise going to the direct-voltage converter G′ via a measuring resistor R′_{Meas}. Measuring resistor R′_{Meas} is part of the current regulating circuit RC′, which includes, additionally, a resistor R1′ and an operational amplifier OP′ connected thereafter.

Likewise connected to the lead line LL1′ is a computer unit CU′. The terminal voltage Uᵢₙ, applied to the 2-conductor connection CN is fed via a voltage divider UD to the computer unit CU′.

A switch pair SP, which is controlled by an oscillator O′ having a fixedly predetermined oscillation frequency, is provided in the lead line LL2. Connected after the switch pair SP is the direct-voltage converter G′, which cares for a galvanic separation between the primary-side circuit portion and the consumer essentials unit CE′ on the secondary side.

Yet another voltage regulator RG2 is connected with the lead line LL1′. Voltage regulator RG2 is a parallel regulator, which drains off excess current. Connected after voltage regulator RG2 is the DC-DC switching regulator RG3. Regulator RG3 delivers at its output a constant output voltage, which, with the help of the unregulated direct-current converter G′, is converted into the supply voltage of 5.5 V available on the secondary side of the converter. The clocked direct-voltage converter G′ is composed, typically, of three coils CO1, CO2, CO3, after which are placed a rectifying diode D1 and a storage capacitor C2.

As is evident from FIG. 2b, two additional regulators RG2 and RG3 are need for supplying the consumer circuit CC′. The circuit arrangement S′ has a significantly more complex construction that the circuit arrangement S of the invention. It requires a significantly more comprehensive “power management”. Moreover, the power available on the input side must be ascertained via measurement of the terminal voltage. This information must then still be transmitted to the consumer essentials unit CE, in order, there, to make possible an energy matching. Due to the additional regulators, power losses result, which are especially undesired in the case of 2-conductor devices. These disadvantages are overcome by the invention.

The operation of the invention will now be explained in greater detail. The total current I_{S} flowing in the lead lines LL1 and LL2 is set via the modulator unit M. Serving for control of the modulator unit M is the current regulating circuit RC, which determines, as actual value, the total current I_{S} via the voltage drop ΔU₁ across the measuring resistor R_{Meas}. The output signal S1 of the computer unit provides the desired value of the total current I_{S}. Via the operational amplifier OP, the difference between desired value and actual value is amplified and fed to the input IN1 of the comparator K. Applied to the second input of comparator K is a reference voltage. The output signal of the comparator K is shown in FIG. 3 for two different, total-current values I_{S}. The pulse width of the output signal S2 of the comparator K is relatively narrow for small values of the total current I_{S} and wider for greater values. The pulses at the output of the oscillator O are passed through to the transistors T1 and T2, respectively, corresponding to the pulse width of the output signal S2 of the comparator K.

The total current I_{S} carried by the field device F1 via the 2-conductor connection CN can be adjusted in simple manner via the current regulating circuit RC and the modulator unit M. No other additional circuit elements are necessary. The energy available at the 2-conductor connection CN is transferred to the consumer circuit CC, quasi without loss, apart from the loss at the measuring resistor R_{Meas}.

If more energy is available to the consumer circuit CC than is being consumed, then the excess current I_{Shunt} must be removed via the shunt resistor R_{Shunt}. The voltage drop ΔU₂ across the shunt resistor R_{Shunt} is, in such case, directly proportional to the power available in the consumer circuit CC. This voltage drop can be exploited, in order to switch-in, on occasion, other units or functionalities of the consumer essentials unit CE, other units which have an increased energy consumption. In this way, the available power can be optimally utilized. The excess current is removed on the consumer side and, when necessary, minimized.

The measured value ascertained by the sensor is transmitted, galvanically separated, to the computer unit CU, which ascertains therefrom the desired value S1 for the total current I_{S}.

The invention permits, in simple manner, electrical current control and power matching of a field device supplied via a 2-conductor current-loop.

The total current I_{S} carried by the 2-conductor loop CL is adjusted with only one regulated unit, the direct-voltage converter G. Additional voltage regulators can be omitted. No complex power management is necessary. The available power can be ascertained directly in the consumer circuit CC and, as required, matched there.

The invention is suited also for field devices, which are connected to a fieldbus system (e.g. Profibus, Foundation Fieldbus) or which have a HART-interface. Also in such situations, the total current I_{S} can be adjusted by the modulator unit M. Additional components are then necessary in the circuit arrangement S for the digital communication, these being known to those skilled in the art and easily integrated.

While, in the case of field devices for field bus systems, the total current I_{S} is normally constant, it is, nevertheless, advantageous to be able to adjust it. Also, in the case of these field devices, the input voltage can be optimally exploited using the circuit arrangement of the invention.

| | |
|---|---|
| 2-conductor connection | CN, CN′ |
| 2-conductor current-loop | CL |
| AND-gate | AG1, AG2 |
| capacitor | C1, C1′ |
| choke coil | L |
| circuit arrangement | CA |
| coils | CO1, CO2, CO3 |
| comparator | K |
| computer unit | CU, CU′ |
| consumer circuit | CC |
| consumer essentials unit | CE, CE′ |
| current regulating circuit | RC, RC′ |
| current regulator | RG1 |
| DC-DC switching regulator | RG3 |
| direct-voltage converter | G, G′ |
| electrical current signal | I_{S} |
| field device | F1 |
| input circuit | IC |
| input terminals | IT1/IT2, IT1′/IT2′ |
| lead line | LL1, LL2, LL1′, LL2′ |
| lines | L1, L2 |
| measuring resistor | R_{MEAS} |
| measuring resistor | R_{Meas}, R_{Meas}′ |
| modulator unit | M |
| operational amplifier | OP, OP′ |
| oscillator | O |
| output signal | S1, S2 |
| power transistor | T1, T2, T3 |
| pulse output | Ph1, Ph2 |
| receiving unit | RU |
| rectifying diodes | D1, D2 |
| resistor | R1, R1′ |
| shunt-resistor | R_{Shunt} |
| storage capacitor | C2 |
| switch pair | SP |
| voltage divider | UD |
| voltage regulator | RG2 |
| Zener diode | Z |

Translation of German words and symbols in the drawing

FIG. 1:

### Change “EE” to -RU-;

change “LS” to -CL-;
change “ES” to -IC-; and
change “VS” to -CC-.

FIG. 2a:

### Change “S” to -CA-;

change “A” to -CN-;
change “EK” (both occurrences) to -IT-;
change “Stromschleife” (both occurrences) to -current loop-;
change “Primaerseite” to -primary side-;
change “Sekundaerseite” to -secondary side-;
change “Gegentaktwandler/push-pull” to -push-pull converter-;
change “ZL” (both occurrences) to -LL-;
change “Verbraucher” (both occurrences) to -consumer-;
change “SP” (three occurrences) to -CO-;
change “Modulatoreinheit” to -modulator unit-;
change “Oszillator” to -oscillator-;
change “E1” to -IN1-;
change “RS” to -RC-;
change “RE” to -CU-;
change “UG” (both occurrences) to -AG-;
change “VE” to -CE-;
insert-K-;
change “Messverstaerker” to -amplifier-;
change “Mikroprozessor” (both occurrences) to -microprocessor-;
change “ev.” to -or-;
change “VS” to -CC-;
change “Peripherie” to -peripherals-;
change “Sollwert” to -desired value-;
change “Messwert” to -measured value-; and
change “MESS” to -MEAS-.

FIG. 2b:

### Change “A”’ to -CN′-;

change “EK” (both occurrences) to -IT-;
change “Stromschleife” (both occurrences) to -current loop-;
change “Primaerseite” to -primary side-;
change “Sekundaerseite” to -secondary side-;
change “ZL” (both occurrences) to -LL-;
change “Parallel Spannungsregler” to -parallel voltage regulator-;
change “Schaltregler” to -switching regulator-;
change “Transformator DC-DC Wandler nicht geregelt” to -transformer DC-DC
converter non-regulated-;
change “Spannungsversorgung” to -voltage supply-;
change “Verbraucher” (three occurrences) to -consumer-
change “Messverstaerker” to -amplifier-;
change “Mikroprozessor” (both occurrences) to -microprocessor-;
change “Oszillator” to -oscillator-;
change “Konst.” to -const.-;
change “RS” to -RC-;
change “RE” to -CU-;
change “UT” to -UD-;
change “VE” to -CE-;
change “ev.” to -or-;
change “VS” to -CC-;
change “Peripherie” to -peripherals-;
change “Sollwert” (both occurrences) to -desired value-;
change “verfuegbare Leistung” to -available power-;
change “Messwert” to -measured value-; and
change “MESS” to -MEAS-.

FIG. 3:

Change “PH” (both occurrences) to -Ph-; and
change “Komparatorausgang bei” (both occurrences) to -comparator output at-.

1-5. (canceled)

6. A circuit arrangement for supplying a field device of automation technology, comprising:
an input circuit having a 2-conductor connection;
a direct-voltage converter connected thereafter; and a consumer circuit, wherein:
said input circuit (IC) includes a modulator unit (M), which is connected with a current regulating circuit (RC) and with said direct-voltage converter (G) and which controls said direct-voltage converter (G) such that an adjustable total current (I_{S}) is carried by said 2-conductor connection (CN).

7. The circuit arrangement as claimed in claim 6, wherein:
said direct-voltage converter (G) is a push-pull converter.

8. The circuit arrangement as claimed in claim 6, wherein:
said modulator unit (M) includes an oscillator (O) having two pulse outputs (Ph1 and Ph2), whose pulses are masked according to the output signal of a comparator (K) and thereby effect the adjusting of the total current (I_{S}).

9. The circuit arrangement as claimed in claim 6, wherein:
the total current I_{S} is a 4-20 mA signal current.

10. The circuit arrangement as claimed in claim 6, wherein:
circuit is used in a field device working according to the Profibus, Foundation Fieldbus or HART standard.
